(19) United States
(12) Patent Application Publication
(10) Pub. No.: US 2026/0025946 A1
(43) Pub. Date: Jan. 22, 2026

(54) FAN CONTROL SYSTEM FOR COOLING ELECTRONIC APPARATUS

(71) Applicant: CANON KABUSHIKI KAISHA, Tokyo (JP)

(72) Inventor: YUTO KASUMI, Tokyo (JP)

(21) Appl. No.: 19/266,753

(22) Filed: Jul. 11, 2025

(30) Foreign Application Priority Data
Jul. 18, 2024 (JP) 2024-114940

(51) Int. Cl. H05K 7/20; G03B 17/55

(52) U.S. Cl. CPC H05K 7/20209; H05K 7/20136; G03B 17/55

(57) ABSTRACT

An electronic apparatus includes a vibration detector that detects a vibration of the electronic apparatus, and a controller that controls an operation of a fan which cools an inside of the electronic apparatus. The electronic apparatus controls an operation of the fan based on a difference between a first vibration detection result of the vibration detector in a case where the fan is not operated and a second vibration detection result of the vibration detector in a case where the fan is operated.

### BACKGROUND

### Field of the Technology

The present disclosure relates to a fan control system for cooling an electronic apparatus.

### Description of the Related Art

As an electronic apparatus such as a digital camera has the higher functionality or the like, its heat generation amount increases. When the temperature of the electronic apparatus exceeds a threshold temperature, the operation of the electronic apparatus is restricted, and cannot be resumed until the temperature becomes equal to or lower than the threshold temperature. Hence, to prevent an excessive rise of the temperature of the electronic apparatus, and to shorten a time required to lower the temperature of the electronic apparatus, a cooling apparatus such as a fan is needed. In this case, when the fan is rotated, the vibration of the fan may cause a video shake, or the noise caused by the vibration of the fan may be mixed in the sound. Therefore, when recording video or sound, there is a need to control the operation of the fan in consideration of the vibration of the fan.

Japanese Patent Laid-Open No. 2013-221429 describes that, when a state in which the vibration of a fan mounted in an electronic apparatus is larger than a predetermined threshold continues for a long time, the fan is determined to have an abnormality. Japanese Patent Laid-Open No. 2012-48653 describes that the vibration of a hard disk drive and the vibration of a fan mounted in an electronic apparatus are detected, and the rotational speed of the fan is controlled in accordance with the vibration detection results.

In Japanese Patent Laid-Open No. 2013-221429, since the vibration threshold used to determine an abnormality of the fan is a fixed value, when the vibration generated due to a factor other than the operation of the fan continues for a long time, the fan is determined to have an abnormality even if the vibration of the fan is smaller than the threshold. When the electronic apparatus is a digital camera or the like, a vibration due to a camera shake by a photographer and a vibration caused by an image blur correction mechanism, which optically corrects an object blur by moving an image sensor in a direction orthogonal to the optical axis direction, are generated. Therefore, when the vibration threshold used to determine an abnormality of the fan is set to a fixed value and the operation of the fan is controlled, as in Japanese Patent Laid-Open No. 2013-221429, the operation of the fan is controlled based on the vibration other than the vibration of the fan even if the vibration of the fan is smaller than the threshold so no abnormality is determined.

In Japanese Patent Laid-Open No. 2012-48653, at least two sensors for detecting the vibration of the hard disk drive and the vibration of the fan are needed. When the electronic apparatus is a digital camera or the like, a sensor for detecting the vibration of the camera is mounted, which is necessary for image blur correction. However, when a sensor for detecting the vibration of the fan is added separately from the sensor for image blur correction, as in Japanese Patent Laid-Open No. 2012-48653, additional cost, adjustment of the sensor output, and the like are required.

### SUMMARY

The present disclosure has been made in consideration of the aforementioned problems, and is directed to an electronic apparatus comprising: a vibration detector that detects a vibration of the electronic apparatus; and a controller that controls an operation of a fan which cools an inside of the electronic apparatus, wherein the controller controls an operation of the fan based on a difference between a first vibration detection result of the vibration detector in a case where the fan is not operated and a second vibration detection result of the vibration detector in a case where the fan is operated.

The present disclosure is directed to a control method of an electronic apparatus comprising: detecting a vibration of the electronic apparatus; and controlling an operation of a fan that cools an inside of the electronic apparatus, wherein the controlling includes controlling an operation of the fan based on a difference between a first vibration detection result in a case where the fan is not operated, and a second vibration detection result in a case where the fan is operated.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIGS. 1A and 1B are perspective views exemplifying an external appearance of an electronic apparatus attached with a cooling apparatus according to a present embodiment;

FIGS. 2A and 2B are perspective views exemplifying an external appearance of the electronic apparatus according to the present embodiment;

FIGS. 3A and 3B are perspective views exemplifying an external appearance of the cooling apparatus according to the present embodiment;

FIGS. 4A to 4C are perspective views exemplifying an internal configuration of the electronic apparatus according to the present embodiment;

FIG. 5 is an exploded perspective view exemplifying a configuration of the cooling apparatus according to the present embodiment;

FIG. 6 is a sectional view of the electronic apparatus attached with the cooling apparatus according to the present embodiment;

FIG. 7 is a block diagram exemplifying control configurations of the electronic apparatus and the cooling apparatus according to the present embodiment;

FIG. 8 is a flowchart exemplifying control processing of a cooling apparatus according to a first embodiment; and

FIG. 9 is a flowchart exemplifying control processing of a cooling apparatus according to a second embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### <System Configuration>

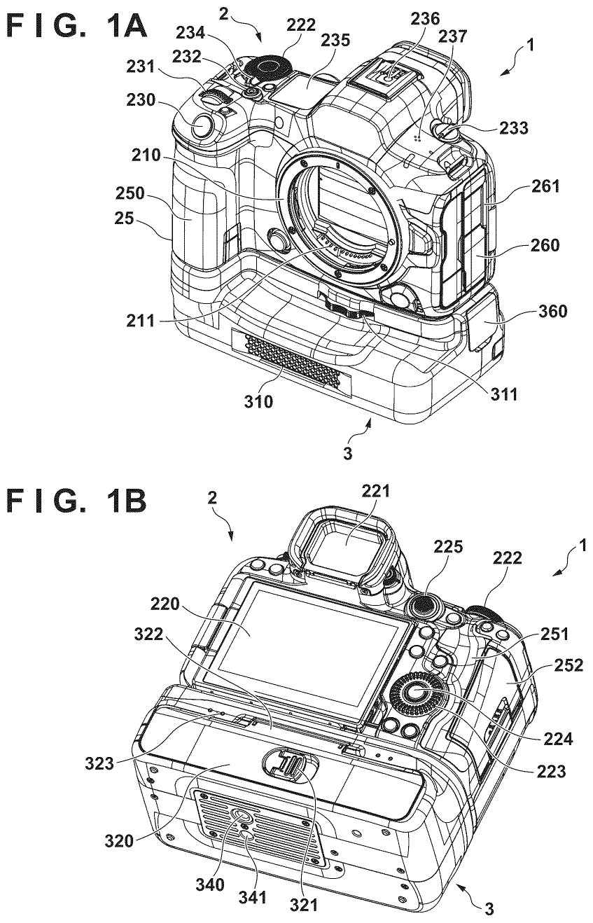

With reference to FIGS. 1A and 1B, a system configuration according to a present embodiment will be described.

FIGS. 1A and 1B are perspective views exemplifying the external appearance of a system according to the present embodiment.

A system 1 according to the present embodiment includes an electronic apparatus 2 and an accessary apparatus 3.

The electronic apparatus 2 is an image capture apparatus capable of shooting a still image and a moving image, that is an interchangeable lens digital camera in the present embodiment. As the electronic apparatus according to the present embodiment, FIGS. 1A and 1B exemplify the camera body 2 with a lens unit detached therefrom.

The accessary apparatus 3 is attachable to and detachable from the camera body 2. In the present embodiment, the accessary apparatus 3 is a cooling apparatus that lowers the temperature inside the electronic apparatus 2. At the same time, the accessary apparatus 3 is a heat dissipation module that is a battery apparatus for supplying power to the electronic apparatus 2. Note that in the present embodiment, the configuration will be described in which the accessary apparatus 3 is formed separately from the electronic apparatus 2 and mechanically and electrically connected to the electronic apparatus 2. However, the configuration may be used in which the accessary apparatus 3 is incorporated in the electronic apparatus 2.

Note that in the present embodiment, an example will be described in which the electronic apparatus 2 is applied to an interchangeable lens digital camera (single lens reflex type or mirrorless type). However, the electronic apparatus 2 is not limited to this example, and may be, for example, an integrated lens digital camera, a digital video camera, a smartphone, a tablet computer, or another apparatus to which the accessary apparatus 3 can be attached.

### <Configurations of Digital Camera and Heat Dissipation Module>

Next, with reference to FIGS. 1A to 6, the configurations and functions of the camera body 2 and the heat dissipation module 3 according to the present embodiment will be described.

FIG. 1A is a front perspective view exemplifying the external appearance of the camera body with a lens unit detached therefrom and the external appearance of the heat dissipation module attachable to the camera body. FIG. 1B a back perspective view exemplifying the external appearance of the camera body with a lens unit detached therefrom and the external appearance of the heat dissipation module attachable to the camera body.

Note that, a description will be given below assuming that the object side of the camera body 2 is the front-face side, the photographer side of the camera body 2 is the back-face side, and the left, right, upper, and lower sides when viewed from the back-face side of the camera body 2 are the left-face side, right-face side, upper-face side, and lower-face side, respectively. Only the main components of the camera body 2 and the heat dissipation module 3 according to the present embodiment will be described below.

First, the configuration of the camera body 2 according to the present embodiment will be described.

As shown in FIG. 1A, the camera body 2 includes a mount 210, to/from which an interchangeable lens unit (not shown) can be attached/detached, in the central portion on the front-face side. Inside the mount 210, a communication terminal 211 used by the camera body 2 to communicate with a lens unit is provided. On the upper-face side of the camera body 2, a shutter button 230 for issuing a shooting instruction, a main electronic dial 231 used to change various kinds of setting values and the like, a moving image button 232 for issuing moving image shooting (recording) start and stop instructions, a shooting mode switching switch 233 for switching between a still image shooting mode and a moving image shooting mode, a power supply switch 234 for switching between ON and OFF of the power supply of the camera body 2, an upper-face side display unit 235 for displaying various kinds of setting values of the camera body 2, an accessary shoe 236 used to attach an accessory apparatus such as an external microphone to the camera body 2, and a sound input unit 237 for obtaining the sound around the camera body 2 during shooting are provided. On the left-face side of the camera body 2, a connector (not shown) used to connect an external device such as an external microphone to the camera body 2, a protection cover 260 for protecting the connector, and an exhaust port 261 are provided. The exhaust port 261 is an outlet through which the air taken from a suction port 310 is exhausted through the heat dissipation module 3 and the camera body 2. On the right-face side of the camera body 2, a grip portion 25 used by a photographer to grip the camera body 2 is provided. The grip portion 25 has a shape, that allows a photographer to easily hold the camera body 2 with the right hand, from the front-face side to the back-face side of the camera body 2. To prevent hand slipping, a front-face rubber member 250 and a back-face rubber member 251 are provided on the front-face side and the back-face side, respectively.

As shown in FIG. 1B, the camera body 2 includes, in the central portion on the back-face side, a back-face display unit 220 for displaying a shot image and various kinds of information. On the upper-face side of the camera body 2, an eyepiece viewfinder 221 formed from an electronic viewfinder is provided. On the right-face side of the camera body 2, various kinds of operation members such as a sub electronic dial 222 and a back-face electronic dial 223 used to change various kinds of setting values and the like, like the main electronic dial 231, a SET button 224 used to determine a selection item and the like, and a multi-controller 225 are provided. The multi-controller 225 can be operated by pressing the key top, as well as tilting the key top in a tilt direction, and is used mainly to move a selection frame, and to move and select in various kinds of setting menus. On the right-face side of the camera body 2, a card lid 252 used to protect a card slot (not shown) for housing a recording card is provided, and arranged in a part of the grip portion 25 to be gripped by a photographer.

Next, the configuration of the heat dissipation module 3 according to the present embodiment will be described.

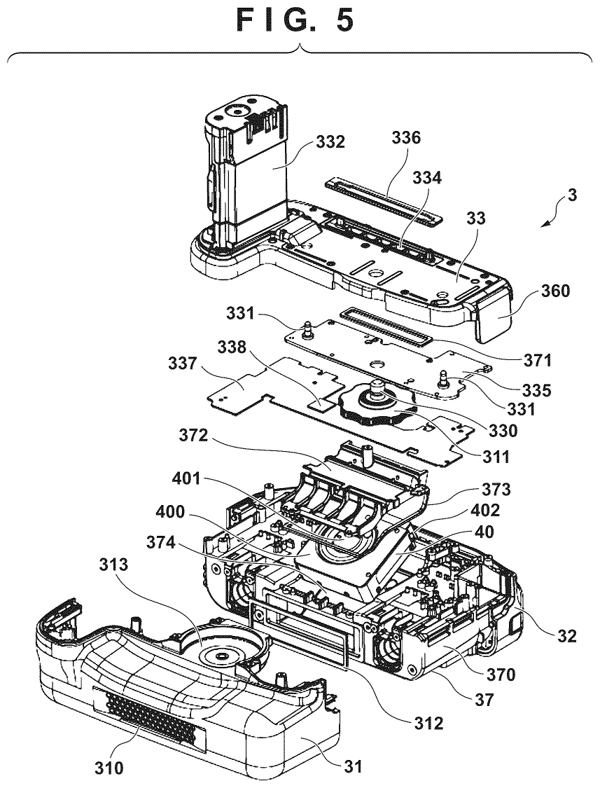

As shown in FIG. 1A, the heat dissipation module 3 includes the suction port 310 in the central portion on the front-face side. The suction port 310 serves as an inlet for taking the surrounding air into a fan 40 (see FIG. 5) arranged inside the heat dissipation module 3. In the central portion on the upper-face side of the heat dissipation module 3, a screw dial 311 is provided, which is an operation member for rotating a male screw member (not shown) used to fix the camera body 2 and the heat dissipation module 3. On the left-face side of the heat dissipation module 3, a connector (not shown) used to connect the camera body 2 and an external device via the heat dissipation module 3, and a protection cover 360 for protecting the connector are provided.

As shown in FIG. 1B, the heat dissipation module 3 includes a battery lid 320 extending in the left-right direction on the back-face side. The battery lid 320 includes a battery lid knob 321 in the center. By lifting and rotating the battery lid knob 321, the battery lid 320 is opened and closed. The battery lid 320 opens due to the biasing force of a spring with a battery lid shaft portion 322 as the rotation axis. A fan lamp 323 is provided on the left-face side of the battery lid shaft portion 322. The fan lamp 323 is turned on when the fan rotates, and is turned off when the fan does not rotate. With this, a photographer can grasp the driving state of the fan. On the lower-face side of the heat dissipation module 3, a female screw member 340 used to fix the system 1 (the heat dissipation module 3 attached to the camera body 2) to a tripod or the like, and a video boss hole 341 that prevents rotational deviation of the system 1 by engaging with a video boss provided on a video camera tripod are provided.

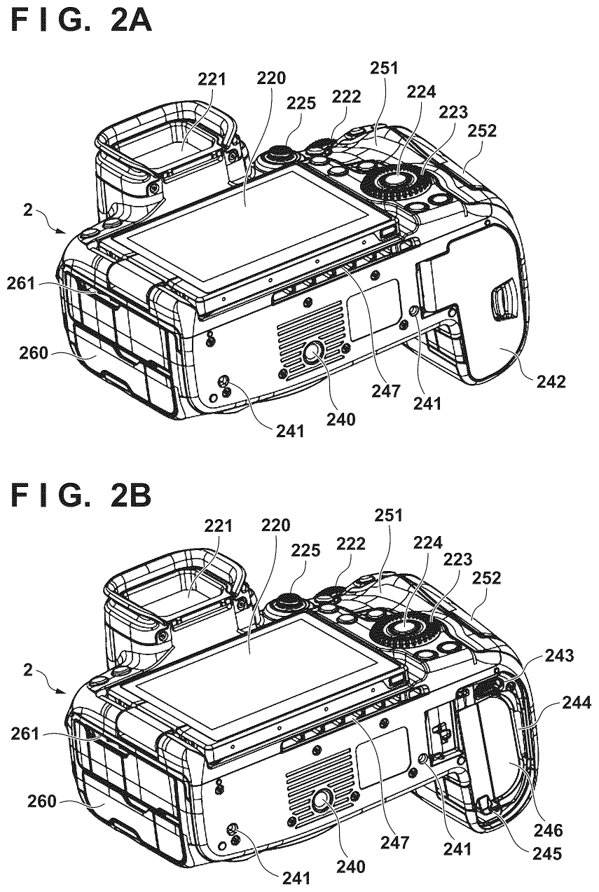

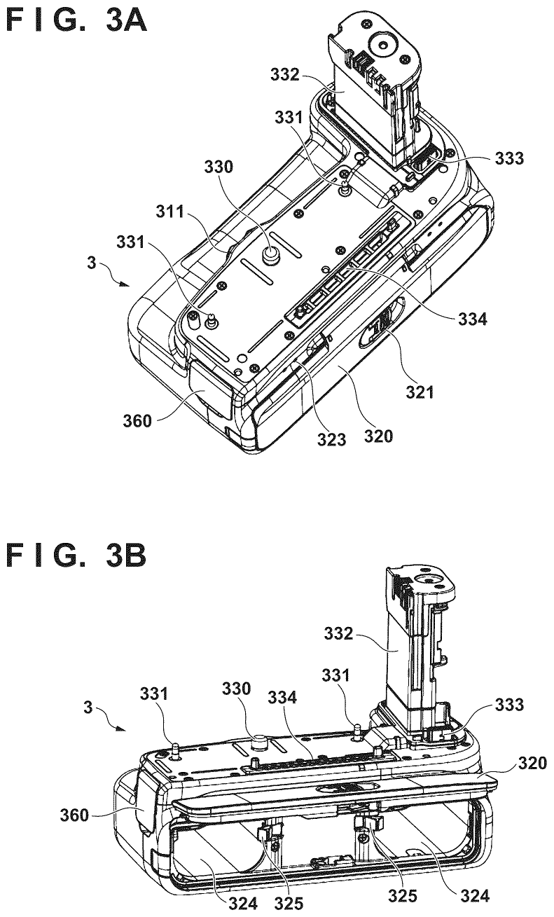

Next, with reference to FIGS. 2A to 3B, the configuration of the camera body 2 on the lower-face side and the back-face side and the configuration of the heat dissipation module 3 on the upper-face side and the back-face side according to the present embodiment will be described.

FIG. 2A is a perspective view exemplifying a state in which a battery lid 242 of the camera body 2 is attached. FIG. 2B is a perspective view exemplifying a state in which the battery lid 242 of the camera body 2 is removed. FIG. 3A is a perspective view exemplifying a state in which the battery lid 320 of the heat dissipation module 3 is closed when viewed from the upper-face side. FIG. 3B is a perspective view exemplifying a state in which the battery lid 320 of the heat dissipation module 3 is opened when viewed from the back-face side.

As shown in FIGS. 2A and 2B, on the lower-face side of the camera body 2, a camera female screw member 240, positioning holes 241, the battery lid 242, a receptacle connector 243, a battery chamber 244, and a battery lock lever 245 are provided. When using the camera body 2 alone, the camera female screw member 240 is used to fix the camera body 2 to a tripod or the like. However, in the present embodiment, the camera female screw member 240 is used to fix the dissipation module 3. The positioning holes 241 are used to align the camera body 2 and the heat dissipation module 3 relative to each other by being engaged with positioning pins 331 (see FIGS. 3A and 3B) of the heat dissipation module 3. The battery lid 242 is attached when using the camera body 2 alone, but is removed when using the camera body 2 with the heat dissipation module 3 attached thereto.

As shown in FIG. 2B, when the battery lid 242 is removed, the receptacle connector 243, the battery chamber 244, a battery 246, and the battery lock lever 245 are exposed on the lower-face side of the camera body 2. The camera body 2 is electrically connected to various kinds of accessories including the heat dissipation module 3 via the receptacle connector 243. When the heat dissipation module 3 is attached to the camera body 2, the receptacle connector 243 is communicatively connected to a plug connector 333 of the heat dissipation module 3, and exchanges data with the heat dissipation module 3. The battery chamber 244 houses the battery 246. The battery lock lever 245 holds the battery 246 even when the battery lid 242 is not closed, thereby preventing the battery 246 from falling out. When the battery 246 is inserted into the battery chamber 244, the terminal of the battery 246 and the battery contact piece in the battery chamber 244 are connected, and power is supplied from the battery 246 to the camera body 2.

As shown in FIG. 3A, on the upper-face side of the heat dissipation module 3, a male screw member 330, the positioning pins 331, a tower portion 332, the plug connector 333, and a blowing port 334 are provided. The male screw member 330 is rotated interlockingly with the operation of the screw dial 311 and threadably engaged with the camera female screw member 240, thereby fixing the camera body 2 and the heat dissipation module 3. The positioning pins 331 are engaged with the positioning holes 241 of the camera body 2, thereby aligning the camera body 2 and the heat dissipation module 3 relative to each other. When attaching the heat dissipation module 3 to the camera body 2, the tower portion 332 is inserted into the battery chamber 244 with the battery lid 242 removed therefrom, and covers the battery chamber 244 instead of the battery lid 242. By the tower portion 332 being inserted into the battery chamber 244, the power supply terminal at the distal end of the tower portion 332 is connected to the battery contact piece in the battery chamber 244, and electric power is supplied from the battery (not shown) housed in the heat dissipation module 3 to the camera body 2 instead of the battery 246. The heat dissipation module 3 is electrically connected to the camera body 2 via the plug connector 333. When the heat dissipation module 3 is attached to the camera body 2, the plug connector 333 is communicatively connected to the receptacle connector 243 of the camera body 2, and exchanges data with the camera body 2. The blowing port 334 serves as an outlet for sending the air exhausted from the fan to a vent port 247 of the camera body 2 from the heat dissipation module 3.

As shown in FIG. 3B, in a state in which the battery lid 320 is opened, a battery chamber 324 and a battery lock lever 325 are provided in each of left and right parts on the back-face side of the heat dissipation module 3. The battery chambers 324 can house two batteries at maximum. A battery (not shown) for driving at least the fan of the heat dissipation module 3 is housed in the battery chamber 324, but the battery is also used to supply power from the heat dissipation module 3 to the camera body 2. In this case, improvement of the driving time of the camera body 2 can be expected. Considering the usability for a user, the battery housed in the heat dissipation module 3 is desirably the same type as the battery 246 that is used to drive the camera body 2.

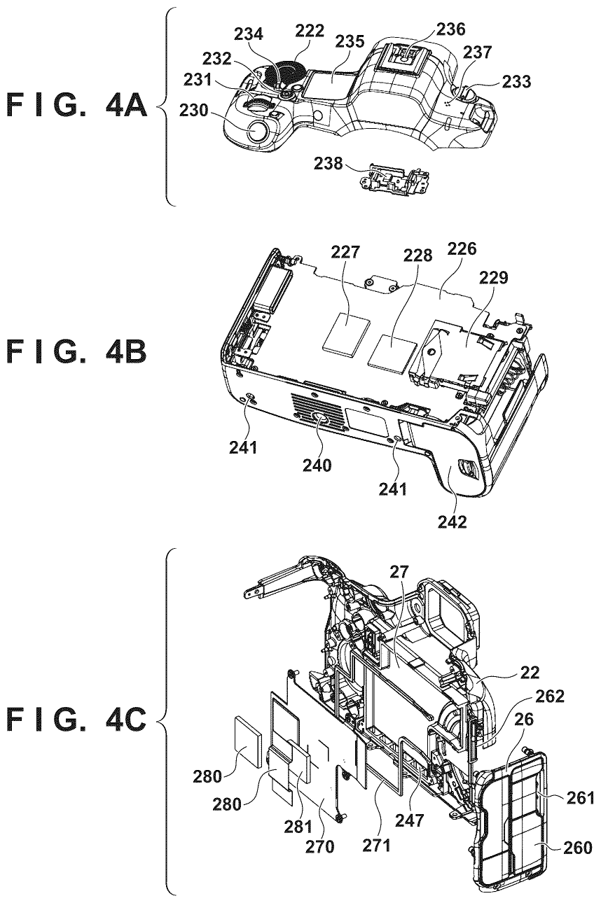

Next, with reference to FIGS. 4A to 4C, the internal configuration of the camera body 2 according to the present embodiment will be described.

FIG. 4A is an developed view of an upper-face cover portion of the camera body 2, exemplifying the internal configuration of the camera body 2. FIG. 4B is a perspective view of the camera body 2 with a back-face cover portion removed therefrom, exemplifying the internal configuration of the camera body 2. FIG. 4C is an exploded perspective view showing the back-face cover portion and a side-face cover portion, exemplifying the internal configuration of the camera body 2.

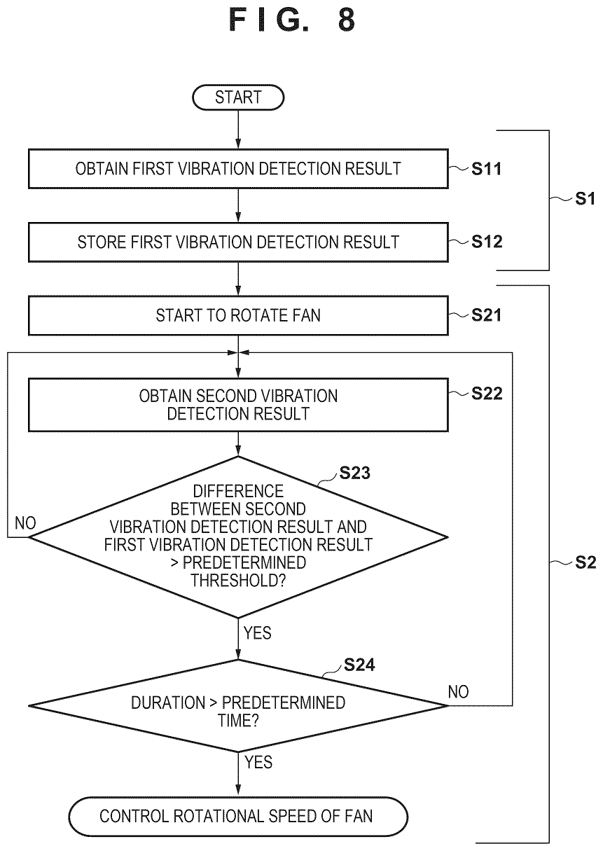

As shown in FIG. 4A, in order to control an image blur correction mechanism and the like, the camera body 2 includes, inside thereof in the central portion on the upper-face side, a vibration detection unit 238 that detects a vibration of the camera body 2. The image blur correction mechanism is a mechanism that moves an image sensor in a direction orthogonal to the optical axis direction by using an electromagnetic actuator such as a voice coil to optically correct an object blur. In FIG. 4A, a gyro sensor is exemplified as the vibration detection unit 238. The gyro sensor vibrates an oscillator inside the sensor, and detects the rotational angular velocity from the modulation of vibration due to a Coriolis force. When using the camera body 2 alone, or when the heat dissipation module 3 is attached to the camera body 2 but the fan of the heat dissipation module 3 is not rotated, the vibration due to the camera shake by the photographer is mainly input to the gyro sensor. On the other hand, when the heat dissipation module 3 is attached to the electronic apparatus 2 and the fan of the heat dissipation module 3 is operated, the vibration of the fan is input to the gyro sensor in addition to the vibration due to the camera shake by the photographer. Therefore, when controlling the operation of the fan based on the vibration of the fan, it is necessary to prevent that the operation of the fan is controlled because the vibration due to the camera shake by the photographer is added even though the influence of the vibration of the fan is small. More specifically, it is necessary to control the operation of the fan based on only the vibration of the fan by extracting the vibration of the fan from the vibration detection result in which the vibration due to the camera shake by the photographer and the vibration of the fan are mixed. To achieve this, in the present embodiment, by controlling the rotational speed of the fan based on the difference between the vibration detection result in a case where the fan is not rotated and the vibration detection result in a case where the fan is rotated, the control is performed while extracting only the vibration of the fan. Control processing of the fan will be described later with reference to FIG. 8. Note that the gyro sensor is exemplified as the vibration detection unit 238 in the present embodiment, but the vibration detection unit 238 is not limited to this, and may be an acceleration sensor or the like as long as it can detect a vibration. The camera body 2 also includes, inside thereof on the left side of the upper face, the sound input unit 237 that picks up the sound around the camera body 2 during shooting. When using the camera body 2 alone, or when using the camera body 2 with the heat dissipation module 3 attached thereto, in a case where the fan of the heat dissipation module 3 is not rotated, the vibration due to the camera shake by the photographer and the vibration caused by the image blur correction mechanism are mainly input to the sound input unit 237. On the other hand, in a case where the fan of the heat dissipation module 3 attached to the camera body 2 is rotated, the vibration of the fan is input to the sound input unit 237 in addition to the vibration due to the camera shake by the photographer and the vibration caused by the image blur correction mechanism. Furthermore, when the rotational speed of the fan is high, the vibration of the fan increases and the noise caused by the vibration of the fan is picked up. Note that in the present embodiment, the sound input unit 237 is a microphone incorporated in the camera body 2. However, even when an external microphone or the like and detachable from the camera body 2 is used, the vibration of the fan can propagate and the noise can be picked up by the microphone. To prevent this, in the present embodiment, by controlling the rotational speed of the fan based on only the vibration of the fan, the noise caused by the vibration of the fan is reduced from being picked up by the sound input unit 237.

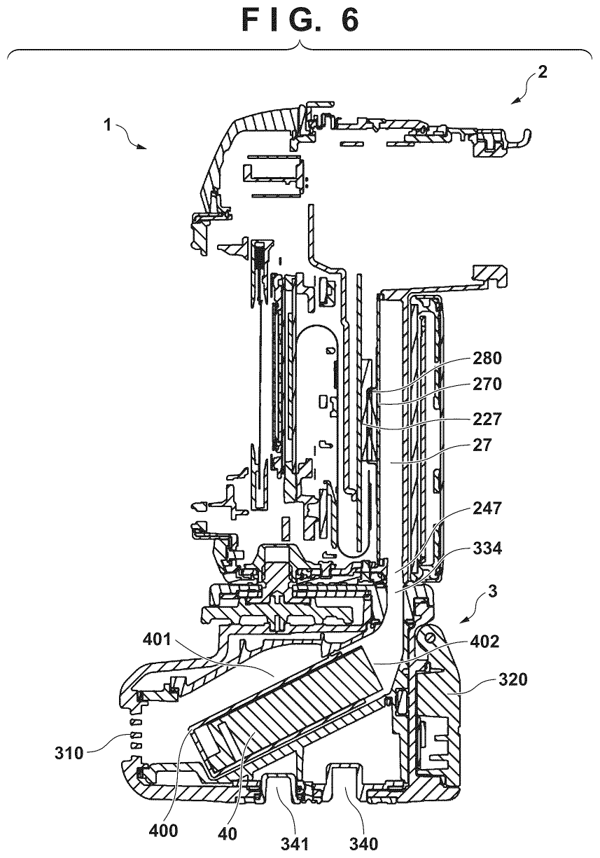

As shown in FIG. 4B, the camera body 2 includes a main board 226 on the back-face side. On the main board 226, power supply circuit components (not shown) for supplying power to the respective parts of the camera body 2 including the heat dissipation module 3, Integrated Circuits (IC) chips 227 and 228 such as a CPU for performing control processing and a GPU for performing image processing, and the like are mounted. On the main board 226, a ROM (not shown) storing programs for control processing, image processing, and the like, a RAM (not shown) for temporarily storing data required for control processing or image processing, a memory card slot 229, a connector (not shown), and the like are also mounted. Note that, for the sake of simplicity, some mounted components, harnesses, and the like on the board are not shown in FIG. 4B. Each of the IC chips 227 and 228 is a device serving as a main heat source on the main board 226 and, during moving image shooting with a high resolution or a high frame rate, its heat generation amount increases since it performs image processing or the like while consuming a large amount of power. Therefore, the IC chips 227 and 228 are arranged so as to face a camera duct 27 (see FIGS. 4A to 4C and FIG. 6) on the back-face side of the camera body 2. The heat generated by each of the IC chips 227 and 228 is transmitted to a heat dissipation sheet metal 270 (see FIG. 4C) provided on the back-face cover portion via a heat transfer member 280 (see FIG. 4C) such as a heat conductive sheet, and dissipated by the air sent from the heat dissipation module 3. When the heat dissipation module 3 is attached to the camera body 2 but the fan of the heat dissipation module 3 is not rotated, the RAM (not shown) mounted on the main board 226 temporarily stores the vibration detection result of the vibration detection unit 238.

As shown in FIG. 4C, the camera body 2 includes the camera duct 27 from a back-face cover 22 to a side-face cover 26. The camera duct 27 includes the vent port 247 on the central lower side of the back-face cover 22, and the exhaust port 261 in the side-face cover 26. The vent port 247 is an inlet for taking the air sent from the blowing port 334 of the dissipation module 3 into the camera duct 27. The camera duct 27 is formed from the back-face cover 22, the side-face cover 26, the heat dissipation sheet metal 270 using aluminum or the like having good thermal conductivity, and a back-face seal member 271 such as Poron or double-sided tape. By fixing the heat dissipation sheet metal 270 to the back-face cover 22 via the back-face seal member 271 and fixing the side-face cover 26 to the back-face cover 22 via an exhaust port seal member 262, an air flow channel communicating from the vent port 247 to the exhaust port 261 is formed. The heat transfer member 280 such as a heat conductive sheet is adhered to the heat dissipation sheet metal 270. In the present embodiment, the heat transfer member 280 is adhered using a cushion member 281, double-sided tape, or the like so as to contact each of the IC chips 227 and 228 serving as the main heat sources, and transfers the heat generated by the IC chips 227 and 228 to the heat dissipation sheet metal 270.

Next, with reference to FIG. 5, the internal configuration of the heat dissipation module 3 according to the present embodiment will be described.

FIG. 5 is an exploded perspective view of the heat dissipation module 3. Note that, for the sake of simplicity, some mounted components, harnesses, and the like on the board, fastening members, and the like are not shown in FIG. 5.

As shown in FIG. 5, the heat dissipation module 3 is formed from a front-face cover portion 31 on the front-face side, a back-face cover portion 32 on the back-face side, an upper-face cover portion 33 on the upper-face side, and a main body portion 37 as the internal structure. The front-face cover portion 31 includes the suction port 310, a suction port seal member 312, and a screw dial seat 313. The back-face cover portion 32 includes the above-described battery lid 320 and fan lamp 323. The upper-face cover portion 33 includes the tower portion 332, the blowing port 334, and a blowing port seal member 336. The main body portion 37 includes a main body case 370, a main body case seal member 371, a main body cover 372, a main body cover seal member 373, the fan 40, a fan cover 400, the screw dial 311, the male screw member 330, an upper-face plate 335, the positioning pins 331, and an accessary board 337. The main body case 370 includes the battery chambers 324 capable of housing two batteries at maximum, and a fan accommodation portion 374 that is opened on the upper-face side. The fan 40 and the fan cover 400 are housed in the fan accommodation portion 374, and arranged obliquely such that a fan exhaust port 402 of the fan 40 is directed to the blowing port 334. Note that in the present embodiment, as the fan 40, a centrifugal fan that takes in air from a fan suction port 401 provided in the blade rotation axis direction and exhausts air from the fan exhaust port 402 provided in the blade rotation radial direction is used. However, an axial flow fan that sucks and exhausts air in the blade rotation axis direction may also be used. In the present embodiment, the fan 40 is obliquely arranged so that the fan exhaust port 402 is directed to the blowing port 334, but may be arranged in the horizontal direction or the vertical direction. The fan cover 400 is formed from an elastic member made of silicone rubber or the like, and reduces propagation of the vibration of the fan 40 to the structural members of the heat dissipation module 3. On the accessary board 337, a fan control unit 338 that controls the rotational speed of the fan 40 is mounted. The fan control unit 338 is formed as an IC chip including a CPU, a memory, and the like. Note that the fan control unit 338 is arranged on the accessary board 337 of the heat dissipation module 3 in the present embodiment, but the fan control unit 338 may be arranged on the main board 226 of the camera body 2. When the front-face cover portion 31 is fixed to the main body case 370 via the suction port seal member 312, the main body cover 372 is fixed to the main body case 370 via the main body cover seal member 373, and the upper-face cover portion 33 is fixed to the main body case 370 and the main body cover 372 via the main body case seal member 371, an air flow channel communicating from the suction port 310 to the blowing port 334 is formed. In addition, by the blowing port seal member 336 provided around the blowing port 334, that prevents air leakage with respect to the camera body 2, an air flow channel communicating from the suction port 310 of the heat dissipation module 3 to the exhaust port 261 of the camera body 2 is formed. Furthermore, when the respective components are fixed without any gaps by these seal members, air leakage from the air flow channel to the inside of the camera body 2 and that to the inside of the heat dissipation module 3, and intrusion of water, dust, and the like are prevented.

Next, with reference to FIG. 6, the flow channel configurations of the camera body 2 and the heat dissipation module 3 according to the present embodiment will be described.

FIG. 6 is a sectional view of the camera body 2 attached with the heat dissipation module 3, which is taken in the vertical direction along the optical axis. For the sake of simplicity, various kinds of mounted components including the board, harnesses, fastening members, and the like are not shown in FIG. 6.

As shown in FIG. 6, when the fan 40 is rotated, the surrounding air is taken from the suction port 310, and the taken air is taken into the fan 40 from the fan suction port 401 of the fan 40 installed obliquely. Thereafter, the air is exhausted from the fan exhaust port 402 in the blade rotation radial direction by the blade rotation of the fan 40. The exhausted air flows in the upper-face direction along the wall portion of the heat dissipation module 3, and is exhausted from the blowing port 334. The air exhausted from the blowing port 334 enters the camera duct 27 from the vent port 247 of the camera body 2, and is exhausted from the exhaust port 261 described above. In this case, the air passing through the camera duct 27 comes into contact with the heat dissipation sheet metal 270 and dissipates heat from the heat dissipation sheet metal 270, and dissipates heat of the IC chips 227 and 228 via the heat transfer member 280.

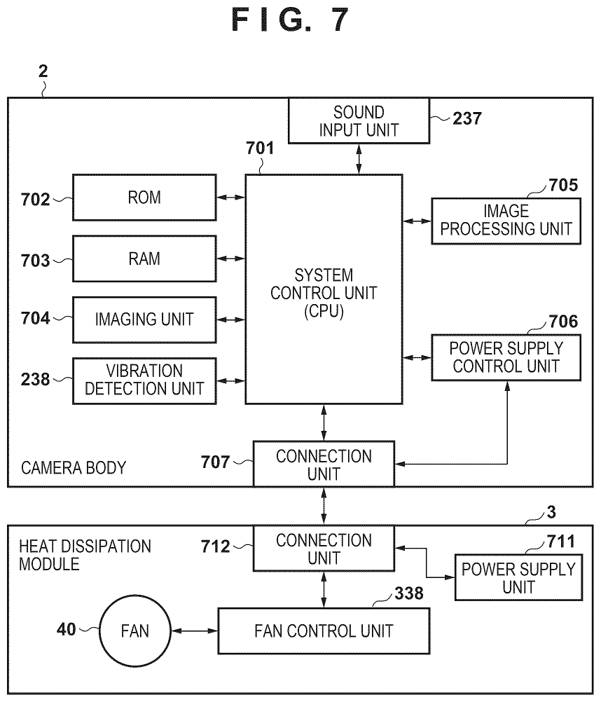

Next, with reference to FIG. 7, the control configurations of the camera body 2 and the heat dissipation module 3 according to the present embodiment will be described.

FIG. 7 is a block diagram exemplifying the control configurations of the camera body 2 and the heat dissipation module 3 according to the present embodiment.

The camera body 2 includes a system control unit 701, a ROM 702, a RAM 703, an imaging unit 704, an image processing unit 705, a power supply control unit 706, a connection unit 707, the sound input unit 237, and the vibration detection unit 238.

The system control unit 701 includes a processor (CPU) that performs control processing of the camera body 2 attached with the heat dissipation module 3.

The ROM 702 stores a program to be executed by the CPU. The RAM 703 temporarily stores a constant, a variable, or the like for executing the program. The system control unit 701 controls each component of the camera body 2 by loading the program stored in the ROM 702 to the RAM 703 and executing it.

The imaging unit 704 includes an image sensor constituted by a CCD, a CMOS sensor, or the like that converts the object image formed by a lens unit into an electrical signal, and an A/D converter that converts an analog video signal output from the image sensor into a digital signal. Under the control of the system control unit 701, the imaging unit 704 converts object image light formed by the lens unit into an electrical signal by the image sensor, performs noise reduction processing and the like, and outputs video data formed from a digital signal.

The image processing unit 705 includes a processor (GPU) that performs image processing. The image processing unit 705 performs pixel interpolation, resizing processing such as reduction, and color conversion processing on video data captured by the imaging unit 704. Also, the image processing unit 705 compression-encodes still image data having undergone image processing by the JPEG format or the like, or encodes moving image data by a moving image compression method such as the MP4 format to generate a video file and record it on a recording medium or the like. The system control unit 701 performs autofocus (AF) processing and auto exposure (AE) processing by performing predetermined arithmetic processing using captured video data, and controlling the focus lens, stop, and shutter of the lens unit based on the obtained arithmetic result.

In the present embodiment, the system control unit 701 and the image processing unit 705 are configured as hardware such as the IC chips 227 and 228.

The power supply control unit 706 controls a power supply unit 711 of the heat dissipation module 3 to control power supply to each component of the camera body 2 and the heat dissipation module 3.

The connection unit 707 includes an interface that is mechanically and electrically connected to a connection unit 712 of the heat dissipation module 3. The connection unit 707 includes a communication terminal (for example, the receptacle connector 243) for communicatively connecting to the heat dissipation module 3, and a power supply terminal for exchanging power with the heat dissipation module 3.

The sound input unit 237 is incorporated in the camera body 2, or is connected to the camera body 2 via the sound terminal of the camera body 2. The sound input unit 237 converts an analog sound signal, that is generated by picking up the sound around the camera body 2, into a digital signal and outputs it to the system control unit 701.

The vibration detection unit 238 detects the vibration of the camera body 2. Based on the vibration detection result of the vibration detection unit 238, the system control unit 701 determines the driving amount of the fan 40 of the heat dissipation module 3, and controls the rotational speed of the fan 40 based on the driving amount. The heat dissipation module 3 includes the power supply unit 711, the connection unit 712, the fan control unit 338, and the fan 40.

The power supply unit 711 is a primary battery such as an alkaline battery or a lithium battery, or a rechargeable secondary battery such as an NiCd battery, an NiMH battery, or an Li ion battery. In the present embodiment, the power supply unit 711 is the battery 246 housed in the battery chamber 244 of the camera body 2.

The connection unit 712 includes an interface that is mechanically and electrically connected to the connection unit 707 of the camera body 2. The connection unit 712 includes a communication terminal (for example, the plug connector 333) for communicatively connecting to the camera body 2, and a power supply terminal for exchanging power with the camera body 2.

The fan control unit 338 controls the rotational speed of the fan 40 based on the driving amount of the fan 40 received from the system control unit 701.

### First Embodiment

Next, with reference to FIG. 8, control processing of a fan 40 according to a first embodiment will be described.

FIG. 8 is a flowchart exemplifying control processing of the rotational speed of the fan 40 of a heat dissipation module 3 according to the first embodiment.

The processing shown in FIG. 8 is implemented by a system control unit 701 loading a program stored in a ROM 702 to a RAM 703 and executing it. The processing shown in FIG. 8 is started when a camera body 2 is powered on, repeated at a predetermined cycle, and terminated when the camera body 2 is powered off.

Step S1 is the processing in a case where the fan 40 is not rotated, and step S2 is the processing in a case where the fan 40 is rotated. When the camera body 2 is powered on in a state in which the heat dissipation module 3 is attached to the camera body 2, the processing transitions to step S1.

In step S11, the system control unit 701 obtains the first vibration detection result of the vibration detection unit 238 for a predetermined time in the case where the fan 40 is not rotated. In step S12, the system control unit 701 stores the first vibration detection result obtained in step S11 in the RAM 703, and transitions to step S2.

In step S21, the system control unit 701 starts to rotate the fan 40. In step S22, the system control unit 701 obtains the second vibration detection result of the vibration detection unit 238 for a predetermined time in the case where the fan 40 is rotated. In step S23, the system control unit 701 compares the second vibration detection result obtained in step S22 and the first vibration detection result obtained in step S12. When the difference between the second vibration detection result and the first vibration detection result is smaller than a predetermine threshold (NO), the system control unit 701 determines that the possibility of a sound input unit 237 picking up the noise caused by the vibration of the fan 40 is low, and returns to step S22. When the difference between the second vibration detection result and the first vibration detection result is larger than the predetermine threshold (YES), the system control unit 701 determines that the possibility of the sound input unit 237 picking up the noise caused by the vibration of the fan 40 is high, and transitions to step S24. In step S24, the system control unit 701 determines whether the duration of a state in which the difference between the second vibration detection result and the first vibration detection result is larger than the predetermined threshold is longer than a predetermined time. When the duration of a state in which the difference between the second vibration detection result and the first vibration detection result is larger than the predetermined threshold is not longer than the predetermined time (NO), the system control unit 701 determines that the second vibration detection result of the vibration detection unit 238 is large due to a temporary vibration caused by a camera shake or the like other than the vibration of the fan 40, and returns to step S22. When the duration of a state in which the difference between the second vibration detection result and the first vibration detection result is larger than the predetermined threshold is longer than the predetermined time (YES), the system control unit 701 determines that the possibility of the sound input unit 237 picking up the noise caused by the vibration of the fan 40 is high, and controls the rotational speed of the fan 40.

According to the first embodiment, the first vibration detection result in the case where the fan 40 is not rotated and the second vibration detection result in the case where the fan 40 is rotated are used in determination to control the operation of the fan 40. With this, it is possible to extract the vibration caused by the rotation of the fan 40 separately from the vibration due to the camera shake by the photographer and the vibration caused by the image blur correction mechanism, that are also generated in the case where the fan 40 is not rotated, and control the rotational speed based on only the vibration of the fan 40. In addition, by determining whether the state in which the difference between the second vibration detection result in the case where the fan 40 is rotated and the first vibration detection result in the case where the fan 40 is not rotated is larger than the predetermined threshold continues for a predetermined time, it is possible to prevent that the rotational speed of the fan 40 is controlled based on the vibration other than the fan 40 even though the vibration of the fan 40 itself is small.

### Second Embodiment

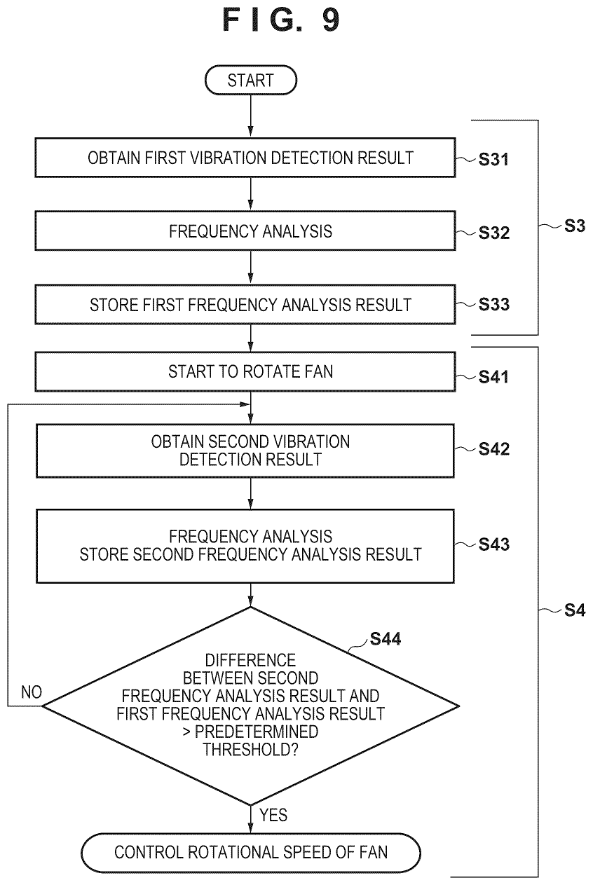

Next, with reference to FIG. 9, control processing of a fan 40 according to a second embodiment will be described.

In the second embodiment, a frequency analysis is executed on the vibration detection result of a vibration detection unit 238, and the rotational speed of the fan 40 is controlled based on the frequency analysis result.

Note that the configurations of an electronic apparatus 2 and a heat dissipation module 3 are the same as those according to the first embodiment shown in FIGS. 1A to 7.

FIG. 9 is a flowchart exemplifying control processing of the rotational speed of the fan 40 of the heat dissipation module 3 according to the second embodiment.

Step S3 is the processing in a case where the fan 40 is not rotated, and step S4 is the processing in a case where the fan 40 is rotated. In the second embodiment, a frequency analysis for extracting the rotational frequency component of the fan 40 is executed on the vibration detection result of the vibration detection unit 238, and this enables determination with higher accuracy. As the vibration characteristic of the fan 40, it is known that the excitation force tends to be large at a frequency corresponding to the primary rotation cycle of the fan 40. Accordingly, in the case where the fan 40 is rotated, it is expected that the vibration of the rotational frequency component becomes large. Accordingly, by extracting the rotational frequency component of the fan 40 from the vibration detection result of the vibration detection unit 238, it is possible to extract, with higher accuracy, the vibration of the fan 40 that is likely to enter a sound input unit 237 as noise. In addition, in the present embodiment, the fan 40 has a plurality of driving modes in advance, and the initial rotational speed of the fan 40 is set for each driving mode. Therefore, the rotational frequency of the fan 40 can be determined in advance, and the rotational frequency in each driving mode is stored in advance in a ROM 702 or the like.

In FIG. 9, when the camera body 2 is powered on in a state in which the heat dissipation module 3 is attached to the camera body 2, the processing transitions to step S3.

In step S31, a system control unit 701 obtains the first vibration detection result of the vibration detection unit 238 for a predetermined time in the case where the fan 40 is not rotated. In step S32, the system control unit 701 executes a frequency analysis for extracting the rotational frequency component of the fan 40 on the first vibration detection result obtained in step S31. In step S33, the system control unit 701 stores the first frequency analysis result obtained in step S32 in a RAM 703, and transitions to step S4.

In step S41, the system control unit 701 starts to rotate the fan 40. In step S42, the system control unit 701 obtains the second vibration detection result of the vibration detection unit 238 for a predetermined time in the case where the fan 40 is rotated. In step S43, the system control unit 701 executes the frequency analysis for extracting the rotational frequency component of the fan 40 on the second vibration detection result obtained in step S42, stores the second frequency analysis result in the RAM 703, and transitions to step S44.

In step S44, the system control unit 701 compares the second frequency analysis result obtained in step S43 and the first frequency analysis result obtained in step S33. As a result of the determination in step S44, when the difference between the second frequency analysis result and the first frequency analysis result is not larger than a predetermined threshold (NO), the system control unit 701 determines that the possibility of the sound input unit 237 picking up the noise caused by the vibration of the fan 40 is low, and returns to step S42. As a result of the determination in step S44, when the difference between the second frequency analysis result and the first frequency analysis result is larger than the predetermine threshold (YES), the system control unit 701 determines that the possibility of the sound input unit 237 picking up the noise caused by the vibration of the fan 40 is high, and controls the rotational speed of the fan 40.

According to the second embodiment, the first frequency analysis result obtained from the first vibration detection result in the case where the fan 40 is not rotated and the second frequency analysis result obtained from the second vibration detection result in the case where the fan 40 is rotated are used in determination to control the operation of the fan 40. With this, it is possible to detect only the vibration of the rotational frequency component, which has a large excitation force in the vibration of the fan 40 and has a large influence on picking-up of the noise caused by the vibration of the fan 40 by the sound input unit 237, thereby controlling the rotational speed of the fan 40 with higher accuracy.

Note that in the above-described processing operations shown in FIGS. 8 and 9, steps S1 and S3 as the processing in the case where the fan 40 is not rotated are performed in a period from power-on of the camera body 2 to the start of rotation of the fan 40, but the processing is only required to be performed in a period during which the fan 40 is not rotated. For example, the processing may be performed in a period of still image shooting during which there is no influence even if the sound input unit 237 picks up the noise caused by the vibration of the fan 40, a period during which the fan 40 is stopped because the fan 40 is not set to start rotation, a period for stopping the fan 40, which is temporarily set at the start of moving image shooting, or the like. As for the control of the rotational speed of the fan 40, in order to reduce the vibration of the fan 40, it is desirable to stop the fan 40 or decrease the rotational speed of the fan 40. However, if decreasing the rotational speed of the fan 40 causes resonance or the like between the camera body 2 and the heat dissipation module 3 and increases the vibration of the camera body 2, the rotational speed of the fan 40 may be increased. In order to reduce that the noise caused by the vibration of the fan 40 is picked up by the sound input unit 237, in addition to the control of the rotational speed of the fan 40, sound processing may be executed on the sound data output from the sound input unit 237. For example, of the sound data picked up during shooting, the volume level of the rotational frequency may be lowered by a certain amount, cut by a certain amount, or set to the average value of the volume levels of the preceding and succeeding frequencies, or the sound data of the rotational frequency may be removed. In the present embodiment, a gyro sensor capable of detecting vibrations around three axes of an axis in the front-back direction, an axis in the left-right direction, and an axis in the up-down direction is exemplified as the vibration detection unit 238. However, it is not necessary to obtain the vibration detection results around all axes, and the vibration detection result around at least one axis may be obtained. With this, the processing load on the control of the rotational speed of the fan 40 according to the present embodiment can be reduced.

As has been described above, according to the embodiments described above, in determination to control the operation of the fan 40, the vibration detection result or the frequency analysis result in the case where the fan 40 is not rotated and the vibration detection result or the frequency analysis result in the case where the fan 40 is rotated are used. With this, it is possible to extract the vibration of the fan 40 separately from the vibration due to the camera shake by the photographer and the vibration caused by the image blur correction mechanism, that are also generated in the case where the fan 40 is not rotated, and control the rotational speed based on only the vibration of the fan 40.

It is also possible to prevent the vibration of the fan 40 from propagating to the sound input unit 237, thereby reducing that the noise caused by the vibration of the fan 40 is picked up by the sound input unit 237. Since the vibration of the fan 40 is detected based on the vibration detection result of the vibration detection unit 238 provided in the camera body 2, it is unnecessary to add a sensor for detecting the vibration of the fan 40, and vibration detection can be implemented even if the camera body 2 and the heat dissipation module 3 are separate bodies. Note that in each embodiment described above, an example in which the camera body 2 and the heat dissipation module 3 are separate bodies has been described, but the heat dissipation module 3 may be integrated in the camera body 2, and the camera body 2 and the heat dissipation module 3 may be formed integrally.

According to the present disclosure, it is possible to appropriately control a fan in consideration of a vibration generated due to a factor other than the operation of the fan.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-114940, filed Jul. 18, 2024 which is hereby incorporated by reference herein in its entirety.

What is claimed is:

1. An electronic apparatus comprising:
a vibration detector that detects a vibration of the electronic apparatus; and
a controller that controls an operation of a fan which cools an inside of the electronic apparatus,
wherein the controller controls an operation of the fan based on a difference between a first vibration detection result of the vibration detector in a case where the fan is not operated and a second vibration detection result of the vibration detector in a case where the fan is operated.

2. The electronic apparatus according to claim 1, further comprising a memory that stores the first vibration detection result and the second vibration detection result,
wherein in a case where a difference between the second vibration detection result and the first vibration detection result is larger than a predetermined threshold, the controller controls a rotational speed of the fan.

3. The electronic apparatus according to claim 2, further comprising a microphone that picks up sound around the electronic apparatus,
wherein in a case where a difference between the second vibration detection result and the first vibration detection result is larger than the predetermined threshold, the controller determines that a possibility of the microphone picking up noise caused by a vibration of the fan is high.

4. The electronic apparatus according to claim 3, wherein
in a case where a duration of a state in which a difference between the second vibration detection result and the first vibration detection result is larger than the predetermined threshold is longer than a predetermined time, the controller controls the rotational speed of the fan.

5. The electronic apparatus according to claim 4, wherein
the controller performs an operation of stopping the fan or an operation of decreasing the rotational speed of the fan so that the vibration of the fan is reduced.

6. The electronic apparatus according to claim 4, wherein
in a case where decreasing the rotational speed of the fan increases the vibration of the electronic apparatus, the controller increases the rotational speed of the fan.

7. The electronic apparatus according to claim 5, wherein
in addition to controlling the rotational speed of the fan, the controller executes sound processing on sound data input to the microphone to lower a volume level of a rotational frequency of the fan.

8. The electronic apparatus according to claim 1, wherein
the electronic apparatus is an image capture apparatus, and
an external device attachable to and detachable from the image capture apparatus includes the fan.

9. The electronic apparatus according to claim 1, wherein
the electronic apparatus is an image capture apparatus, and
the image capture apparatus includes the fan.

10. The electronic apparatus according to claim 8, wherein
the case where the fan is not operated is one of a period from power-on of the image capture apparatus to rotation of the fan, a period of still image shooting, a period during which the fan is stopped without being set to rotate, and a period for temporarily stopping the fan at a start of moving image shooting.

11. The electronic apparatus according to claim 1, further comprising a memory that stores the first vibration detection result and the second vibration detection result,
wherein the controller stores, in the memory, a first frequency analysis result obtained by executing a frequency analysis for extracting a rotational frequency component of the fan on the first vibration detection result, and a second frequency analysis result obtained by executing the frequency analysis on the second vibration detection result, and
controls the rotational speed of the fan in a case where a difference between the second frequency analysis result and the first frequency analysis result is larger than a predetermined threshold.

12. The electronic apparatus according to claim 11, further comprising a microphone that picks up sound around the electronic apparatus,
wherein in a case where a difference between the second frequency analysis result and the first frequency analysis result is larger than the predetermined threshold, the controller determines that a possibility of the microphone picking up noise caused by a vibration of the fan is high.

13. The electronic apparatus according to claim 12, wherein
in a case where a difference between the second frequency analysis result and the first frequency analysis result is larger than the predetermined threshold, the controller controls the rotational speed of the fan.

14. The electronic apparatus according to claim 13, wherein
the controller performs an operation of stopping the fan or an operation of decreasing the rotational speed of the fan so that the vibration of the fan is reduced.

15. The electronic apparatus according to claim 11, wherein
the electronic apparatus is an image capture apparatus, and
an external device attachable to and detachable from the image capture apparatus includes the fan.

16. The electronic apparatus according to claim 11, wherein
the electronic apparatus is an image capture apparatus, and
the image capture apparatus includes the fan.

17. The electronic apparatus according to claim 16, wherein
the case where the fan is not operated is one of a period from a time when the image capture apparatus is powered on to a time when the fan is rotated, a period of still image shooting, a period during which rotation of the fan is not set so that the fan is stopped, and a period for temporarily stopping the fan at a start of moving image shooting.

18. A control method of an electronic apparatus comprising:
detecting a vibration of the electronic apparatus; and
controlling an operation of a fan that cools an inside of the electronic apparatus,
wherein the controlling includes controlling an operation of the fan based on a difference between a first vibration detection result in a case where the fan is not operated, and a second vibration detection result in a case where the fan is operated.

19. A system including an electronic apparatus and an external device which is attachable to and detachable from the electronic apparatus, wherein
the external device includes a fan that cools an inside of the electronic apparatus,
the electronic apparatus includes a vibration detector that detects a vibration of the electronic apparatus, and
a controller that controls an operation of the fan in a case where the external device is attached to the electronic apparatus, and
the controller controls an operation of the fan based on a difference between a first vibration detection result of the vibration detector in a case where the fan is not operated and a second vibration detection result of the vibration detector in a case where the fan is operated.

20. A non-transitory computer-readable storage medium storing a program for causing a computer to execute the control method of an electronic apparatus comprising:
detecting a vibration of the electronic apparatus; and
controlling an operation of a fan that cools an inside of the electronic apparatus,
wherein the controlling includes controlling an operation of the fan based on a difference between a first vibration detection result in a case where the fan is not operated, and a second vibration detection result in a case where the fan is operated.
